(19) United States
(12) Patent Application Publication
(10) Pub. No.: US 2014/0118984 A1
(43) Pub. Date: May 1, 2014

(54) ELECTRONIC DEVICE AND METHOD OF MANUFACTURING THE SAME

(71) Applicant: Denso Corporation, Kariya-city (JP)

(72) Inventors: Kohei FUJIHARA, Kariya-shi (JP); Kouji KONDOH, Toyohashi-shi (JP); Kazuo TADA, Kariya-shi (JP)

(73) Assignee: Denso Corporation, Kariya-city (JP)

(21) Appl. No.: 14/048,140

(22) Filed: Oct. 8, 2013

(30) Foreign Application Priority Data
Oct. 25, 2012 (JP) 2012-235435

(51) Int. Cl. H05K 3/40; H05K 7/14

(52) U.S. Cl. CPC H05K 3/4038; H05K 7/14
USPC 361/809; 29/852

(57) ABSTRACT

In a method of producing an electronic device, a thermoplastic resin film is sandwiched between an electronic component having electrodes and a mounting member having a substrate to produce a lamination assembly. Via holes are formed in the thermoplastic resin film and filled with conductive paste. Through holes as depressed sections are formed in at least one of an area in the substrate, which faces the thermoplastic resin film, and an area in a connecting section formed on the substrate and which is not contact with the conductive paste in the via holes. The lamination assembly is heated and pressed in a lamination direction, thereof, simultaneously in order to sinter the conductive paste in the via holes. This produces an interlayer connection member in each via hole and the electronic device.

### CROSS-REFERENCE TO RELATED APPLICATION

This application is related to and claims priority from Japanese Patent Application No. 2012-235435 filed on Oct. 25, 2012, the contents of which are hereby incorporated by reference.

### BACKGROUND OF THE INVENTION

1. Field of the Invention

The present invention relates to electronic devices and methods of manufacturing the electronics devices, in which one or more electronic components are mounted on a mounting member through a bonding member.

2. Description of the Related Art

There have been widely known electronic devices in which one or more electronic components are mounted on a mounting member through a bonding member. Such electronic devices use printed circuit board (PCB) as the mounting member. Wiring patterns and connecting sections are formed on a surface of the printed circuit board. One or more semiconductor chips having electrodes are used as the electronic components. For example, a thermoplastic resin film is used as the bonding member in which via holes are formed in the thermoplastic resin film and interlayer connection members are formed in the via holes. The electrodes of the electronics components such as semiconductor chips are electrically connected to the connecting sections of the mounting member through the interlayer connection members formed in the mounting member. For example, Japanese patent laid open publication No. JP 2011-222553 discloses a conventional structure of such an electronic device.

For example, an electronic device can be manufactured by the following method. Via holes are formed in a thermoplastic resin film. Then, the via holes are filled with a conductive paste. The thermoplastic resin film with the via holes is fired or sintered in order to form interlayer connection members in the via holes. This produces a component member which will be used as the bonding member having the via holes. The via holes are filled with the interlayer connection members.

The wiring patterns and the connecting sections are formed on the mounting member. One or more semiconductor chips are mounted on the produced component member as the bonding member. The component member is arranged on the mounting member so that the conductive paste in the via holes are electrically contacted with the connecting sections formed on the mounting member in order to electrically connect the electrodes of the semiconductor chips to the conductive paste. This makes a lamination assembly as the electronic device.

The lamination assembly is heated and pressed in a lamination direction with a predetermined pressure. This causes that the thermoplastic resin contained in the thermoplastic resin film flows out, and as a result, the electronic components and the mounting member are connected through the thermoplastic resin film and the conductive paste is sintered to form the interlayer connection members.

This electrically connects the electrodes of the semiconductor chips with the connecting sections of the mounting member through the interlayer connection members of the bonding member. This makes it possible to form the electronic device as the lamination assembly.

However, the conventional method previously described has a drawback in which the thermoplastic resin easily flows toward a surface direction of the mounting member, i.e. a printed circuit board when the lamination assembly is formed. There is a possibility that the via holes (with the conductive paste) are shifted toward the surface direction of the mounting member, and as a result, a connection fault occurs between the electrodes of the semiconductor chips, the interlayer connection members formed by sintering the conductive paste in the via holes of the bonding member, and the connecting sections of the mounting member.

### SUMMARY

It is therefore desired to provide an electronic device and a method of manufacturing the electronic device capable of suppressing occurrence of connection fault between interlayer connection members formed in via holes of a bonding member, electrodes of electronic components such as semiconductor chips, and connecting sections formed in a mounting member.

An exemplary embodiment provides a method of manufacturing an electronic device. The electronic device is comprised of a mounting member, an electronic component and a bonding member. The mounting member is comprised of a substrate having a surface on which connecting sections are formed. The electronic component has a surface on which electrodes are formed. The surface of the electronic component faces the substrate of the mounting member. The bonding member is comprised of a thermoplastic resin film arranged between the mounting member and the electronic component. Via holes are formed in the thermoplastic resin film and filled with interlayer connection members. The connecting sections are connected to the electrodes of the electronic component through the interlayer connection members.

The method is comprised of a lamination assembly production step and a heating and pressing step. The lamination assembly production step is comprised of the following steps. In the lamination assembly production step, the via holes are formed in the thermoplastic resin film. The via holes are filled with the conductive paste. The depressed sections are formed in at least one of the surface of the substrate of the mounting member, which faces the thermoplastic resin film and the connecting sections so that the depressed sections are apart from the conductive paste. The bonding member, the mounting member and the electronic component are stacked so that the bonding member is sandwiched between the electronic component and the mounting member. In the heating and pressing step, the lamination assembly is heated and pressed in a lamination direction thereof simultaneously in order to sinter the conductive paste in the via holes to produce the electronic device.

Because thermoplastic resin flows into the inside of the depressed sections (or through holes) when the electronic component, the bonding member and the mounting member are bonded together to form the lamination assembly 50, it is possible to suppress the thermoplastic resin from flowing toward a surface direction of the surface of the substrate. This makes it possible to suppress the via holes (which are filled with the conductive paste) from being shifted toward the surface direction on the surface of the substrate. It is therefore possible to avoid occurrence of a connection fault between the connecting sections, the electrodes, and the interlayer connection members generated by sintering the conductive paste.

Another exemplary embodiment provides an electronic device comprised of a lamination assembly composed of a mounting member, an electronic component and a bonding member. The mounting member is comprised of a substrate and connecting sections formed on a surface of the substrate. The electronic component is comprised of electrodes formed on a surface of the electronic component so that the surface of the electronic component faces the surface of the substrate. The bonding member is comprised of a thermoplastic resin film arranged between the mounting member and the electronic component. Via holes are formed in a thickness direction of the thermoplastic resin film to penetrate the thermoplastic resin film. The via holes are filled with interlayer connection members. The thermoplastic resin film is contacted with the connecting sections and the electrodes. In particular, depressed sections are formed in at least one of (a) the surface of the substrate of the mounting member on which the bonding member is arranged, and (b) the connecting sections so that the depressed sections are not contacted with the interlayer connection members. The depressed sections are filled with thermoplastic resin contained in the thermoplastic resin film.

Because thermoplastic resin contained in the thermoplastic resin film flows into the inside of the depressed sections (or through holes), it is possible to suppress the thermoplastic resin from flowing toward a surface direction of the surface of the substrate. This makes it possible to suppress the via holes (which are filled with the conductive paste) from being shifted toward the surface direction on the surface of the substrate. It is therefore possible to avoid occurrence of a connection fault between the connecting sections, the electrodes, and the interlayer connection members.

### BRIEF DESCRIPTION OF THE DRAWINGS

A preferred, non-limiting embodiment of the present invention will be described by way of example with reference to the accompanying drawings, in which:

FIG. 1 is an overall view showing a cross section of an electronic device comprised of a mounting member 10, and a bonding member 20 and an electronic component 30 (a semiconductor chip) according to a first exemplary embodiment of the present invention;

FIG. 2 is a plan view of the mounting member 10 in the electronic device according to the first exemplary embodiment of the present invention shown in FIG. 1;

FIG. 3A is a view showing a cross section of a component member 40, which becomes the bonding member 20, before via holes 22 are filled with a conductive paste 24 in a process of manufacturing the electronic device shown in FIG. 1;

FIG. 3B is a view showing a cross section of the component member 40 after the via holes 22 are filled with the conductive paste 24 in the process of manufacturing the electronic device shown in FIG. 1;

FIG. 4A is a view showing a cross section of the electronic device in the process of manufacturing the electronic device according to the first exemplary embodiment shown in FIG. 1;

FIG. 4B is a view showing a cross section of the electronic device in the process of manufacturing the electronic device according to the first exemplary embodiment shown in FIG. 1;

FIG. 5 is a view showing an electronic device as a modification of the first exemplary embodiment shown in FIG. 1, in which two electronic components 30 (semiconductor chips) are mounted on the mounting member 10 through the bonding member 20;

FIG. 6 is a view showing a cross section of an electronic device according to a second exemplary embodiment of the present invention;

FIG. 7 is a plan view of the mounting member 10-1 in the electronic device according to the second exemplary embodiment of the present invention shown in FIG. 6;

FIG. 8 is a view showing a cross section of an electronic device according to a third exemplary embodiment of the present invention;

FIG. 9 is a plan view of the mounting section 10-2 in the electronic device according to the third exemplary embodiment of the present invention shown in FIG. 8;

FIG. 10 is a view showing a cross section of an electronic device according to a fourth exemplary embodiment of the present invention;

FIG. 11 is a plan view of the mounting member 10 in the electronic device according to the fourth exemplary embodiment of the present invention shown in FIG. 10; and

FIG. 12A to FIG. 12D are views showing cross sections of an electronic device according to a fifth exemplary embodiment of the present invention during a process of manufacturing the electronic device.

### DETAILED DESCRIPTION OF THE PREFERRED EMBODIMENTS

Hereinafter, various embodiments of the present invention will be described with reference to the accompanying drawings. In the following description of the various embodiments, like reference characters or numerals designate like or equivalent component parts throughout the several diagrams.

### First Exemplary Embodiment

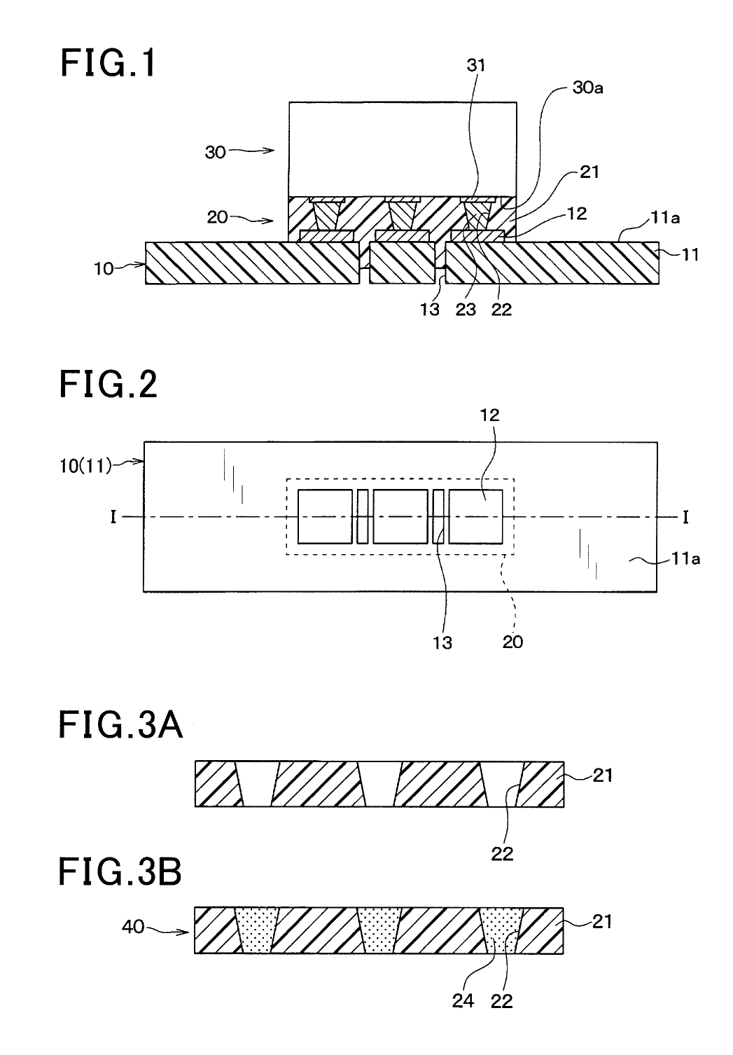

A description will be given of an electronic device and a method of manufacturing the electronic device according to a first exemplary embodiment with reference to FIG. 1 to FIG. 5.

FIG. 1 is an overall view showing a cross section of the electronic device comprised of a mounting member 10, and a bonding member 20 and an electronic component 30 (a semiconductor chip) according to the first exemplary embodiment. As shown in FIG. 1, the electronic device according to the first exemplary embodiment has a structure in which the electronic component 30 (i.e. a semiconductor chip) is mounted onto the mounting member 10 through the bonding member 20.

In particular, the mounting member 10 is a printed circuit board (PCB), etc. in which wiring patterns (omitted from drawings) and connecting sections 12 are formed on a surface 11a of a substrate 11 having a rectangle shape.

FIG. 2 is a plan view of the mounting member 10 in the electronic device according to the first exemplary embodiment of the present invention shown in FIG. 1. As shown in FIG. 2, each of the three connecting sections 12 has a rectangle shape and arranged in a longitudinal direction of the substrate 11 of the mounting member 10. However, the shape of the connecting sections is not limited.

For example, the substrate 11 in the mounting member 10 is made of a glass epoxy substrate, and the wiring pattern (not shown) is made of copper (Cu), etc. The cross section of the electronic device shown in FIG. 1 is obtained using the I-I line which crosses the electronic device shown in FIG. 2.

As shown in FIG. 1 and FIG. 2, a plurality of through holes 13 is formed in the substrate 11 along a thickness direction of the substrate 11 as the mounting member 10. That is, the two through holes 13 are formed in the area of the substrate 11, which correspond in position to the bonding member 20. As shown in FIG. 2, in the structure of the electronic device according to the first exemplary embodiment, the two through holes 13 are formed in the area of the substrate 11, which corresponds to the area in the bonding member 20 in which no connecting section is formed.

Each of the through holes 13 corresponds to a depressed section used in the claims of the present invention. The through holes 13 will be explained in detail later. A thermoplastic resin flows into the through holes 13 as the depressed sections during the manufacturing of the electronic device. That is, the thermoplastic resin flows from the surface 11a of the substrate 11 into the inside of the through holes 13 formed in the substrate 11. As shown in FIG. 1, an upper half of each of the through holes 13 at the surface 11a side of the substrate 11 is filled with the thermoplastic resin. The dotted line in FIG. 2 indicates the bonding member 20 arranged on the mounting member 10.

The bonding member 20 is made of a thermoplastic resin film 21. Via holes 22 are formed at the position in the thermoplastic resin film 21 which correspond to the connecting sections 12 of the mounting member 10. The via holes 22 penetrate in a thickness direction of the thermoplastic resin film 21. Further, an interlayer connection member 23 is formed in each of the via holes 22. Each of the interlayer connection members 23 is electrically connected to the corresponding connecting section 12 of the mounting member 10.

In the electronic device according to the first exemplary embodiment, each of the via holes 22 has a tapered shape in which a diameter of the via hole 22 is gradually decreased toward the mounting member 10 side, as shown in FIG. 1. However, the concept of the present invention is not limited by this structure of the via holes 22. It is possible for each of the via hoes 22 to have another tapered shape in which the diameter of the via hole 22 is gradually increased toward the mounting member 10 side or the via hole 22 has a constant diameter, i.e. has a cylindrical shape.

The interlayer connection member 23 is formed by sintering a conductive paste 24. The conductive paste 24 is obtained by adding organic solvent such as paraffin to metal particles of Ag—Sn, etc. The thermoplastic resin film 21 has a glassy-transition temperature which is higher than a sintering temperature of metal particles which form the interlayer connection member 23, and lower than a melting point of the mounting member 10 and the electronic component 30 (a semiconductor chip).

The electronic component 30 is comprised of a semiconductor chip, etc. The electronic component 30 has a plurality of electrodes 31 at a surface thereof. When the electrodes 31 are electrically connected to the interlayer connection members 23 formed in the via holes 22, the electrodes 31 of the electronic component 30 are electrically connected to the connecting sections 12 through the interlayer connection members 23 formed in the via holes 22.

The electronic device according to the first exemplary embodiment has the improved structure previously described.

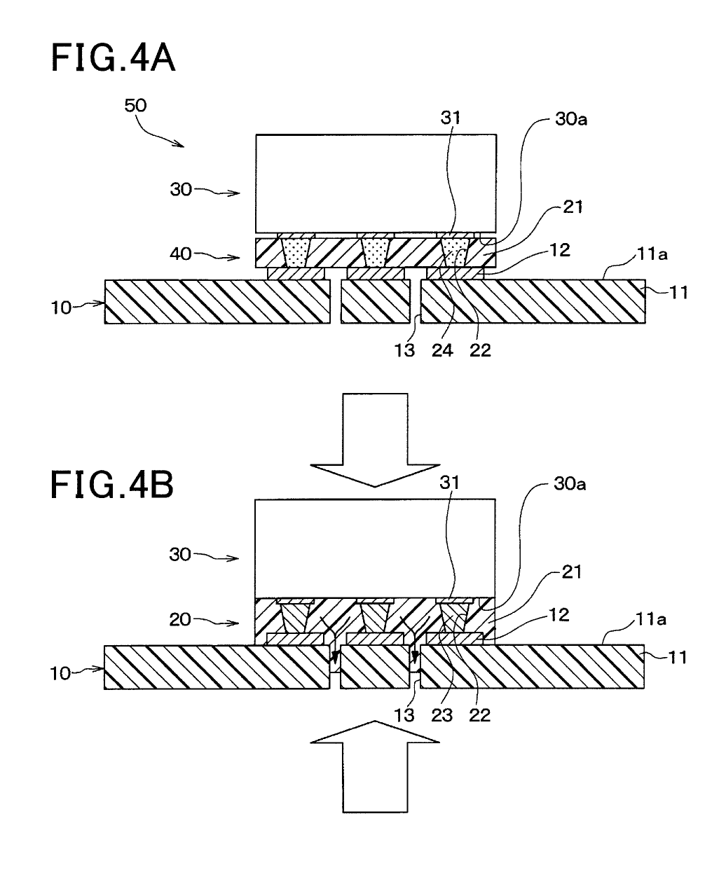

Next, a description will now be given of the method of manufacturing the electronic device having the structure previously described according to the first exemplary embodiment with reference to FIG. 3A, FIG. 3B, FIG. 4A and FIG. 4B.

FIG. 3A is a view showing a cross section of a component member 40 before the via holes 22 are filled with the conductive paste 24 in a process of manufacturing the electronic device according to the first exemplary embodiment shown in FIG. 1. FIG. 3B is a view showing a cross section of the component member 40 after the via holes 22 are filled with the conductive paste 24 in the process of manufacturing the electronic device according to the first exemplary embodiment shown in FIG. 1.

In the method of manufacturing the electronic device, as shown in FIG. 3A, the thermoplastic resin film 21 is prepared. The via holes 22 are formed in the thermoplastic resin film 21 by using a gas laser, etc.

As shown in FIG. 3B, the via holes 22 are then filled with the conductive paste 24. This produces the component member 40. The conductive paste 24 is composed of a paste obtained by adding organic solvent such as paraffin to metal particles of Ag—Sn having a melting point of 480° C.

It is possible to use a device capable of filling the conductive paste 24 into the via holes 22 which is disclosed, for example in a patent document JP 2010-50356.

In a brief explanation, the thermoplastic resin film 21 is placed on a supporting table through an adsorption paper so that a back surface of the thermoplastic resin film 21 faces the adsorption paper on the supporting table. The adsorption paper is a wood free paper which is easily available on the commercial market. That is, it is sufficient to use a paper so long as it can absorb the organic solvent contained in the conductive paste 24.

The via holes 22 are filled with the conductive paste 24 while the conductive paste 24 is melted. At this process, because the wood free paper adsorbs the organic solvent contained in the conductive paste 24, it is possible to fill the vial holes 22 with the metal particles contained in the conductive paste 24.

FIG. 4A and FIG. 4B are views showing a cross section of the electronic device in the manufacturing process according to the first exemplary embodiment shown in FIG. 1.

As shown in FIG. 4A, the mounting member 10 is prepared, in which the wiring patterns (not shown), the connecting sections 12 and the through holes 13 are formed. The component member 40 (made of the thermoplastic resin film 21 having the via holes 22 with the conductive paste 24) is arranged on the mounting member 10 so that the conductive paste 24 in the via holes 22 is electrically contacted with the connecting sections 12, and the electrodes 31 of the electronic component 30 (semiconductor chip) are electrically connected with the conductive paste 24 in the via holes 22. The through holes 13 are formed in the substrate 11. The surface 11a of the substrate 11 faces the connecting sections 12 and the component member 40 (as the thermoplastic resin film 21). This produces the lamination assembly 50.

As shown in FIG. 4B, the lamination assembly 50 is comprised of the electronic component 30, the component member 40 and the mounting member 10. The lamination assembly 50 is placed between a pair of pressing boards. The lamination assembly 50 is heated at a predetermined heating temperature and pressed toward a lamination direction thereof simultaneously by a pressing machine, for example. The heating temperature is higher than a sintering temperature of the metal particles contained in the conductive paste 24 in the via holes 22 and a deformation temperature of the thermoplastic resin film 21 in the component member 40 at which the thermoplastic resin film 21 becomes soften, and also higher than a melting point of the mounting member 10 and a melting point of the electronic component 30.

The thermoplastic resin contained in the thermoplastic resin film 21 is softened, and the softened thermoplastic resin flows on the surface 30a of the electronic component 30. The thermoplastic resin bonds the electronic component 30 on the bonding member 20. Further, the softened thermoplastic resin also flows on the surface 11a of the substrate 11 of the mounting 10 and bonds the bonding member 20 on the mounting member 10. Still further, the conductive paste 24 in the via holes 22 is heated and pressed simultaneously by flowing the softened thermoplastic resin. This makes it possible to sinter and bond the metal particles together contained in the conductive paste 24. That is, a diffusion bonding is formed between the metal particles, the connecting sections 12 and the electrodes 31 of the electronic component 30. That is, the interlayer connection members 23 are formed in the via holes 22. As a result, the electrodes 31 of the electronic component 30 are electrically connected to the connecting sections 12 through the interlayer connection members 23 formed in the via holes 22.

At this time, because the through holes 13 have been formed in the substrate 11, the thermoplastic resin flows into the through holes 13. This makes it possible to prevent the thermoplastic resin from flowing toward the surface 11a of the substrate 11.

As previously described in detail, the method of manufacturing electronic devices according to the first exemplary embodiment uses the substrate 11 in which the through holes 13 are formed. This structure of the substrate 11 makes it possible to suppress the thermoplastic resin from flowing in a surface direction of the surface 11a of the substrate 11 because the thermoplastic resin flows into the inside of the through holes 13 when the electronic component 30, the bonding member 20 and the mounting member 10 are bonded together to form the lamination assembly 50. This also makes it possible to suppress the via holes 22 (which is filled with the conductive paste 24) from being shifted toward the surface direction on the surface 11a of the substrate 11. It is therefore possible to avoid occurrence of a connection fault between the connecting sections 12, the electrodes 31, and the interlayer connection members 23 generated by sintering the conductive paste 24.

In addition, it is possible to adjust the thickness of the bonding members 20 by adjusting an amount of the thermoplastic resin flowing into the through holes 13. That is, the more the amount of thermoplastic resin flowing into the through holes 13 is increased, the more the thickness of the bonding member 20 decreases. On the other hand, the more the amount of thermoplastic resin flowing into the through holes 13 is decreased, the more the thickness of the bonding member 20 increases.

When a plurality of the electronic components 30 is arranged on the mounting member 10, it is possible to form the bonding member 20 having a flat surface (which faces the surface 30a of the electronic component 30). The flat surface of the bonding member 20 has the same height measured from the other surface of the bonding member 20 (which faces the surface 11a of the substrate 11 in the mounting member 10) without changing a size of the surface 11a of the substrate 11.

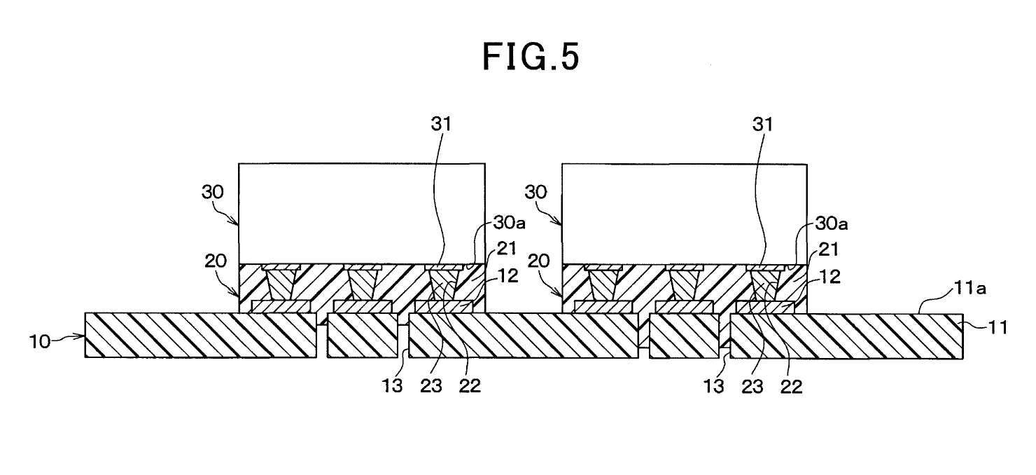

FIG. 5 is a view showing a modification of the electronic device according to the first exemplary embodiment shown in FIG. 1, in which two electronic components 30 (semiconductor chips) are mounted on the mounting member 10 through the bonding member 20.

As shown in FIG. 5, even if each of the component member 40 (which corresponds to the thermoplastic resin film 21) has a slightly different thickness and each of the electronic components 30 has a slightly different thickness, it is possible to form the surface of the bonding member 20 with the same height which is measured from the surface 11a of the mounting member 10 because the thickness of the bonding member 20 is changed by adjusting an amount of thermoplastic resin flowing into the through holes 13.

Further, the electronic device and the method according to the first exemplary embodiment use the conductive paste 24 which contains metal particles of Ag—Sn having a melting point of 480° C. This makes it possible to increase the capability of reflow resistance when components such as the bonding member 20 are mounted on and fixed to the mounting member 10 by solder.

The first exemplary embodiment shows the through holes 13 formed in the substrate 11 as the mounting member 10, which correspond to the area between the adjacent connecting sections 12 in the bonding member 20. However, the concept of the present invention is not limited by this structure. It is of course possible to form the through holes 13 at desired positions, for example, in the outside areas of the connecting sections 12 in the bonding member 20.

### Second Exemplary Embodiment

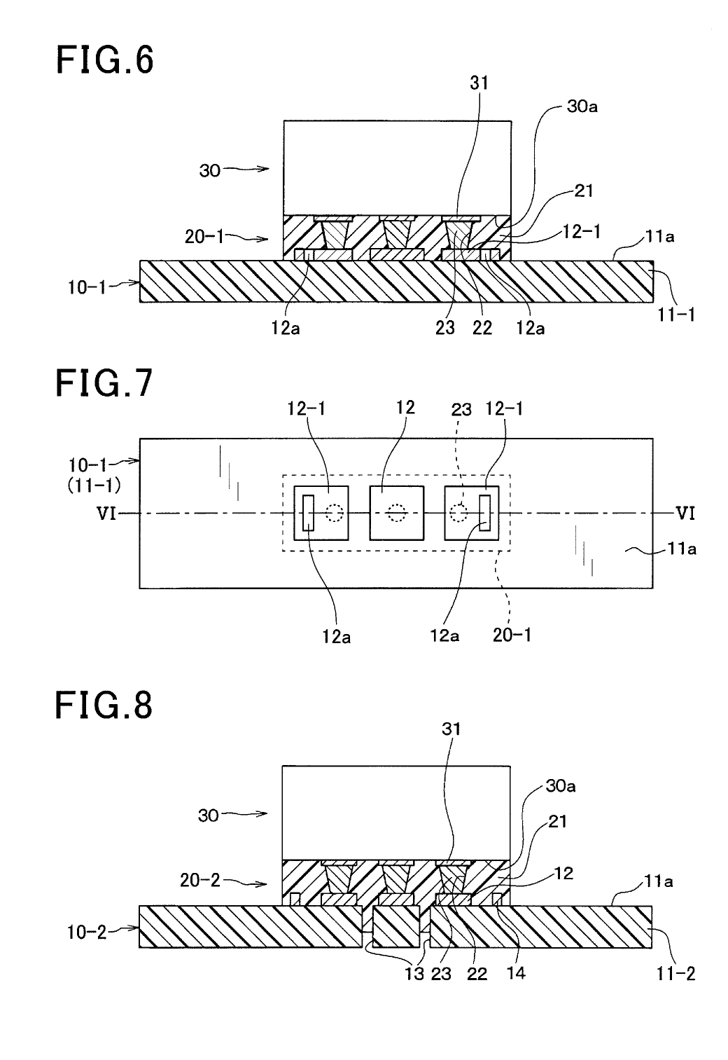

A description will be given of the electronic device and method according to a second exemplary embodiment with reference to FIG. 6 and FIG. 7.

The first exemplary embodiment shows the electronic device having the structure in which the through holes 13 are formed in the mounting member 10 as previously described. However, the concept of the present invention is not limited by this structure.

The second exemplary embodiment shows the electronic device having another structure in which through holes 12a are formed in connecting sections 12-1 in a bonding member 20-1. Other components in the electronic device according to the second exemplary embodiment have the same structure and function of the components in the electronic device according to the first exemplary embodiment. The explanation of the same components is omitted here.

FIG. 6 is a view showing a cross section of the electronic device according to the second exemplary embodiment. FIG. 7 is a plan view of the mounting member 10-1 in the electronic device according to the second exemplary embodiment shown in FIG. 6.

As shown in FIG. 6 and FIG. 7, the bonding member 20-1 in the electronic device according to the second exemplary embodiment has three connecting sections 12 and 12-1. In particular, as shown in FIG. 6 and FIG. 7, through holes 12a are formed in the two connecting sections 12-1. The two connecting sections 12-1 are formed at both the side areas in the bonding member 20-1. The connecting sections have a plate shape.

The cross section of the electronic device comprised of the electronic component 30, the bonding member 20-1 and the mounting member 10-1 in the electronic device shown in FIG. 6 is obtained using the VI-VI line which crosses the electronic device shown in FIG. 7. The dotted line in FIG. 7 indicates the bonding member 20-1 arranged on the mounting member 10-1.

The method of manufacturing the electronic device according to the second exemplary embodiment performs the same processes of the method according to the first exemplary embodiment excepting a process of preparing the mounting member 10-1 having the through holes 12a.

In the method of manufacturing the electronic device according to the second exemplary embodiment, the thermoplastic resin flows into the through holes 12a formed in the connecting sections 12-1 in the bonding member 20-1 when the electronic component 30, the bonding member 20-1 and the mounting member 10-1 are assembled together to form the lamination assembly. This process makes it possible to prevent the thermoplastic resin from flowing toward a surface direction on the surface 11a of the substrate 11-1 as the mounting member 10-1, and to have the same effects of the electronic device and the method according to the first exemplary embodiment previously described.

The second exemplary embodiment shows the structure in which the three connecting sections 12 and 12-1 are formed in the bonding member 20-1. However, the concept of the present invention is not limited by this structure. It is possible for the bonding member 20-1 to have a structure in which the through hole 12a is formed in one connecting section only, or the through holes 12a are formed in all of the connecting sections. Still further, it is possible to change the position of the connecting section 12-1 in the bonding member 20-1.

### Third Exemplary Embodiment

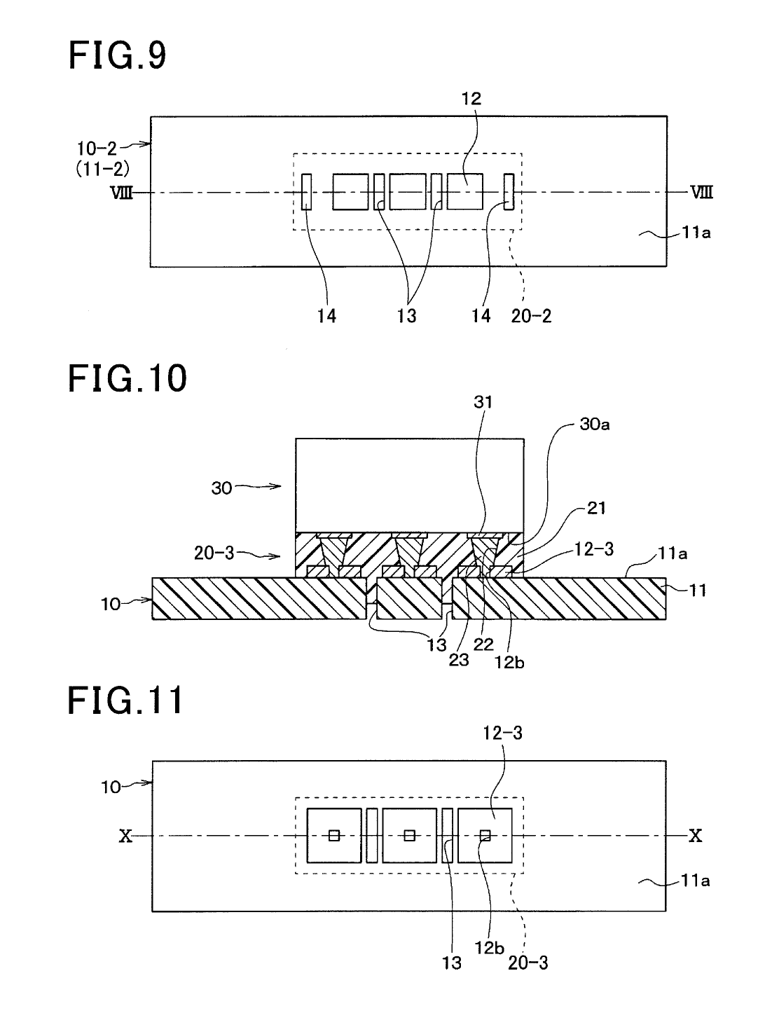

A description will be given of the electronic device and method according to a third exemplary embodiment with reference to FIG. 8 and FIG. 9.

FIG. 8 is a view showing a cross section of the electronic device according to the third exemplary embodiment. FIG. 9 is a plan view of the mounting member 10-2 of the electronic device according to the third exemplary embodiment shown in FIG. 8.

The third exemplary embodiment shows the electronic device having a structure in which two protruding sections 14 are formed on the surface 11a of the substrate 11-2. Other components in the electronic device according to the third exemplary embodiment have the same structure and function of the components in the electronic device according to the first exemplary embodiment. The explanation of the same components is omitted here.

As shown in FIG. 8 and FIG. 9, the two protruding sections 14 are formed at both the outer sides of the bonding member 20-2. That is, each of the protruding sections 14 is formed on the surface 11a of the mounting member 10-2, which corresponds to an outer side of the connecting sections 12 in the bonding member 20-2.

In the structure of the electronic device according to the third exemplary embodiment, the protruding sections 14 are made of copper (Cu), etc. like the connecting sections 12 and the wiring patterns (not shown) formed on the substrate 11-2. Further, the protruding sections 14 are not electrically connected to the connecting sections 12 and the interlayer connection members 23 formed in the via holes 22 in the bonding member 20-2. In other words, the protruding sections 14 are dummy patterns.

The cross section of the electronic device comprised of the electronic component 30, the bonding member 20-2 and the mounting member 10-2 in the electronic device shown in FIG. 8 is obtained using the VIII-VIII line which crosses the electronic device shown in FIG. 9. The dotted line in FIG. 9 indicates the bonding member 20-2 arranged on the mounting member 10-2.

The method of manufacturing the electronic device according to the third exemplary embodiment performs the same processes of the method according to the first exemplary embodiment excepting a process of preparing the mounting member 10-2 having the protruding sections 14.

In the method of manufacturing the electronic device according to the third exemplary embodiment, the protruding sections 14 can prevent the thermoplastic resin from flowing toward a direction of the surface 11a of the substrate 11-2. This process makes it possible to prevent the via holes 22 (filled with the conductive paste 24 or interlayer connection member 23) from being deformed in a surface direction on the surface 11a of the substrate 11-2, and to have the same effects of the electronic device and the method according to the first exemplary embodiment previously described.

The third exemplary embodiment shows the structure of the electronic device in which the two protruding sections 14 are formed on the substrate 11-2. However, the concept of the present invention is not limited by this structure. It is possible for the electronic device to have a structure in which four protruding sections 14 are formed around the connecting section 12, or a structure in which an outer frame is formed around the three connecting sections 12.

### Fourth Exemplary Embodiment

A description will be given of the electronic device and method according to a fourth exemplary embodiment with reference to FIG. 10 and FIG. 11.

FIG. 10 is a view showing a cross section of an electronic device according to the fourth exemplary embodiment. FIG. 11 is a plan view of the mounting member 10 in the electronic device according to the fourth exemplary embodiment shown in FIG. 10.

The electronic device according to the fourth exemplary embodiment has connecting sections 12-2 which are different in shape from the connecting sections 12 disclosed in the first to third exemplary embodiments. Other components in the electronic device according to the fourth exemplary embodiment have the same structure and function of the components in the electronic device according to the first exemplary embodiment. The explanation of the same components is omitted here.

As shown in FIG. 10 and FIG. 11, in the structure of the electronic device according to the fourth exemplary embodiment, a through hole 12b is formed in the connecting section 12-3. The through holes 12b correspond to second depressed sections used in the claims of the present invention. That is, the surface 11a of the substrate 11 is exposed to the interlayer connection member 23 formed in the via hole 22. In other words, the surface 11a of the substrate 11 is directly connected to the electrically interlayer connection members 23 formed in the via holes 22 through the through hole 12b. The through hole 12b corresponds to the depressed section used in the claims of the present invention. As shown in FIG. 10, the interlayer connection members 23 is formed in the via hole 23, and also formed as a wedge in the through hole 12b.

The cross section of the electronic device comprised of the electronic component 30, the bonding member 20-3 and the mounting member 10 in the electronic device shown in FIG. 10 is obtained using the X-X line which crosses the electronic device shown in FIG. 11. The dotted line in FIG. 11 indicates the bonding member 20-3 arranged on the mounting member 10.

The structure of the electronic device according to the fourth exemplary embodiment shown in FIG. 10 and FIG. 11 makes it possible to increase the contact area between the interlayer connection members 23 and the connecting section 12-3. This further increases the strength of connecting the bonding member 20-3 to the substrate 11 of the mounting member 10.

A lamination assembly is comprised of the electronic component 30, a component member 40 (as thermoplastic resin film 21) and the mounting member 10. The lamination assembly in the electronic device according to the fourth exemplary embodiment is manufactured using the following method. The component member 40 is arranged on the mounting member 10 so that the through hole 12 is sealed with the conductive paste 24. The electronic component 30 is arranged on the component member 40 (thermoplastic resin film 21) so that the electrodes 31 of the electronic component 30 are contacted with the conductive paste 24.

### Fifth Exemplary Embodiment

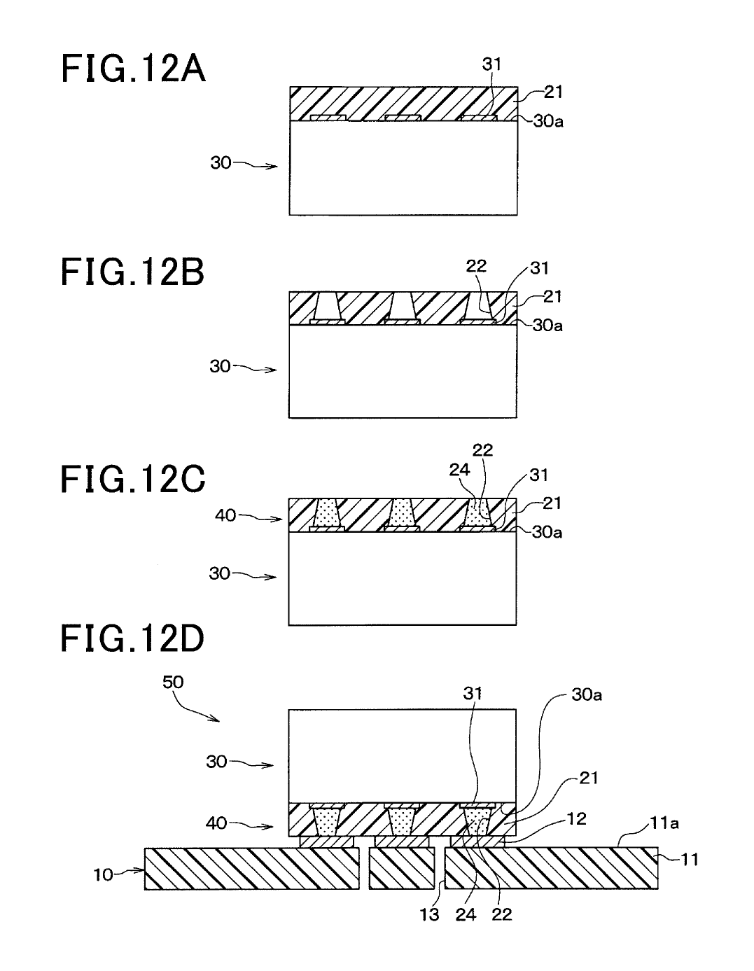

A description will be given of the electronic device and method according to a fifth exemplary embodiment with reference to FIG. 12A to FIG. 12D.

FIG. 12A to FIG. 12D are views showing cross sections of the electronic device according to the fifth exemplary embodiment during a process of manufacturing the electronic device. The fifth exemplary embodiment shows an improved method of producing the lamination assembly. Other components in the electronic device according to the fifth exemplary embodiment have the same structure and function of the components in the electronic device according to the first exemplary embodiment. The explanation of the same components is omitted here.

As shown in FIG. 12A, in the method according to the fifth exemplary embodiment, the thermoplastic resin film 21 is bonded onto the surface 30a of the electronic component 30. In more detail, the thermoplastic resin film 21 is arranged on the surface 30a of the electronic component 30, and the assembly composed of the thermoplastic resin film 21 and the electronic component 30 is pressed with a predetermined pressure while heating the assembly.

As shown in FIG. 12B, a plurality of the via holes 22 is formed in the thermoplastic resin film 21 by using carbon dioxide laser (CO₂ laser), etc. The electrodes 31 of the electronic component 30 are exposed to the corresponding via holes 22 formed in the thermoplastic resin film 21.

As shown in FIG. 12C, the via holes 22 are filled with the conductive paste 24. Because one surface of each of the via holes 22 uses the corresponding electrode 31 of the electronic component 30 in the fifth exemplary embodiment, it is not necessary to use any absorbent paper.

After this, as shown in FIG. 12D, the component member 40 (as the thermoplastic resin film 21) is arranged on the mounting member 50 so that the connecting sections 12 are contacted with the conductive paste 24 in the via holes 22. This makes the lamination assembly 10. After this, the lamination assembly 50 is heated and pressed simultaneously, like the method according to the first exemplary embodiment. The production of the electronic device is completed.

The method according to the fifth exemplary embodiment does not use any absorbent paper. Further, because the electrodes 31 of the electronic component 30 are contacted with the via holes 22, this structure makes it possible to suppress the separation of the conductive paste 24 from the via holes 22 and to suppress the conductive paste 24 from dropping. The fifth exemplary embodiment provides a simple manufacturing process and an easy design of the via holes as well as having the same effects of the first exemplary embodiment.

### (Other Modifications)

In the structure of the electronic device according to the first exemplary embodiment previously described, the through holes 13 which penetrate in the substrate 11 of the mounting member 10 are used as the depressed section defined in the claims of the present invention. However, the concept of the present invention is not limited by this structure. It is possible to use holes which do not penetrate the substrate 11, instead of the through holes 13.

In the structure of the electronic device according to the second exemplary embodiment previously described, the through holes 12a which penetrate in the connecting section 12-1 in the bonding member 20-1 are used as the depressed section defined in the claims of the present invention. However, the concept of the present invention is not limited by this structure. It is possible to use holes which do not penetrate the connecting section 12-1, instead of the through holes 12a.

In the structure of the electronic device according to the fourth exemplary embodiment previously described, the through holes 12b which penetrate in the connecting section 12-3 in the bonding member 20-3 are used as the depressed section defined in the claims of the present invention. However, the concept of the present invention is not limited by this structure. It is possible to use holes which do not penetrate the connecting section 12-3, instead of the through holes 12b.

For example, it is possible to combine two or more of the structures of the electronic devices according to the first, second, third and fourth exemplary embodiments. For example, it is possible to combine the structures of the electronic devices according to the first and second exemplary embodiments. In this case, the through holes 13 are formed in the substrate 11 and the through holes 12a are formed in the connecting sections 12-1.

Further, it is possible to combine the structures of the electronic devices according to the second and third exemplary embodiments. In this case, the through holes 12a are formed in the connecting sections 12-1 and the protruding sections 14 are formed in the substrate 11-2.

Still further, it is possible to combine the structures of the electronic devices according to the second and fourth exemplary embodiments. In this case, the through holes 12a and 12b are formed in the connecting sections of the bonding member.

Furthermore, it is possible to combine the structures of the electronic devices according to the third and fourth exemplary embodiments. In this case, the protruding sections 14 are formed in the substrate 11-2 and the through holes 12b are formed in the connecting sections 12-3.

Furthermore, it is possible to combine the structures of the electronic devices according to the first, second, third and fourth exemplary embodiments. In this case, the through holes 13 and the protruding sections 14 are formed in the substrate 11-2 and the through holes 12a and 12b are formed in the connecting sections.

Still further, it is possible to combine the fifth exemplary embodiments with one or more of the first to fourth exemplary embodiments. In this case, the electronic device 30 equipped with the component member 40 (made of the thermoplastic resin film 21) is arranged on the mounting member 10.

While specific embodiments of the present invention have been described in detail, it will be appreciated by those skilled in the art that various modifications and alternatives to those details could be developed in light of the overall teachings of the disclosure. Accordingly, the particular arrangements disclosed are meant to be illustrative only and not limited to the scope of the present invention which is to be given the full breadth of the following claims and all equivalents thereof.

What is claimed is:

1. A method of manufacturing an electronic device comprised of a mounting member, an electronic component and a bonding member, the mounting member comprised of a substrate having a surface on which connecting sections are formed, the electronic component having a surface on which electrodes are formed, the surface facing the substrate of the mounting member, the bonding member comprised of a thermoplastic resin film arranged between the mounting member and the electronic component, via holes being formed in the thermoplastic resin film and filled with interlayer connection members, and the connecting sections being connected to the electrodes of the electronic component through the interlayer connection members, the method comprising steps of:
producing a lamination assembly comprising steps of:
forming the via holes in the thermoplastic resin film,
filling the via holes with the conductive paste,
forming depressed sections in at least one of the surface of the substrate of the mounting member, which faces the thermoplastic resin film and the connecting sections so that the depressed sections are apart from the conductive paste, and
stacking the bonding member, the mounting member and the electronic component so that the bonding member is sandwiched between the electronic component and the mounting member; and
heating the lamination assembly and pressing the lamination assembly in a lamination direction thereof simultaneously in order to sinter the conductive paste in the via holes to produce the electronic device.

2. The method of manufacturing the electronic device according to claim 1, wherein in the lamination assembly production step, protruding sections are formed on an area of the substrate of the mounting member which is apart from the connecting sections.

3. The method of manufacturing the electronic device according to claim 1, wherein the lamination assembly production step uses the connecting sections of the mounting member in which depressed sections are formed in the connecting sections, and in the lamination assembly production step, the thermoplastic resin film is arranged on the substrate of the mounting member so that the depressed sections are filled with the thermoplastic resin film.

4. The method of manufacturing the electronic device according to claim 2, wherein the lamination assembly production step uses the connecting sections of the mounting member in which depressed sections are formed in the connecting sections, and in the lamination assembly production step, the thermoplastic resin film is arranged on the substrate of the mounting member so that the depressed sections are filled with the thermoplastic resin film.

5. The method of manufacturing the electronic device according to claim 1, wherein in the lamination assembly production step, the via holes are formed in the thermoplastic resin film, and the via holes are filled with the conductive paste, the thermoplastic resin film is arranged on the substrate of the mounting member so that the connecting sections of the mounting member are contacted with the conductive paste in the thermoplastic resin film, and
the electronic component is arranged on the thermoplastic resin film so that the electrodes of the electronic component are contacted with the conductive paste.

6. The method of manufacturing the electronic device according to claim 2, wherein in the lamination assembly production step, the via holes are formed in the thermoplastic resin film, and the via holes are filled with the conductive paste, the thermoplastic resin film is arranged on the substrate of the mounting member so that the connecting sections of the mounting member are contacted with the conductive paste in the thermoplastic resin film, and
the electronic component is arranged on the thermoplastic resin film so that the electrodes of the electronic component are contacted with the conductive paste.

7. The method of manufacturing the electronic device according to claim 1, wherein in the lamination assembly production step, the surface of the electronic component is arranged on the thermoplastic resin film, the via holes are formed in the thermoplastic resin film so that the electrodes of the electronic component are exposed to the thermoplastic resin film, the via holes are filled with the conductive paste, and the electronic component and the thermoplastic resin film are arranged on the mounting member so that the connecting sections of the mounting member are contacted with the conductive paste in the thermoplastic resin film.

8. The method of manufacturing the electronic device according to claim 2, wherein in the lamination assembly production step, the surface of the electronic component is arranged on the thermoplastic resin film, the via holes are formed in the thermoplastic resin film so that the electrodes of the electronic component are exposed to the thermoplastic resin film, the via holes are filled with the conductive paste, and the electronic component and the thermoplastic resin film are arranged on the mounting member so that the connecting sections of the mounting member are contacted with the conductive paste in the thermoplastic resin film.

9. An electronic device comprising:
a mounting member comprised of a substrate and connecting sections formed on a surface of the substrate;
an electronic component comprised of electrodes formed on a surface of the electronic component so that the surface of the electronic component faces the surface of the substrate; and
a bonding member comprised of a thermoplastic resin film arranged between the mounting member and the electronic component, via holes being formed to penetrate the thermoplastic resin film in a thickness direction of the thermoplastic resin film, and the via holes being filled with interlayer connection members, the thermoplastic resin film being contacted with the connecting sections and the electrodes,
wherein depressed sections are formed in at least one of:
(a) the surface of the substrate of the mounting member on which the bonding member is arranged, and
(b) the connecting sections so that the depressed sections are not contacted with the interlayer connection members,
and the depressed sections are filled with thermoplastic resin contained in the thermoplastic resin film.

10. The electronic device according to claim 9, wherein second depressed sections are formed in the connecting sections of the mounting member, and the second depressed sections are filled with the interlayer connection members.
